(19) United States
(12) Patent Application Publication
(10) Pub. No.: US 2012/0285519 A1
(43) Pub. Date: Nov. 15, 2012

(54) GRID DESIGN FOR III-V COMPOUND SEMICONDUCTOR CELL

(75) Inventors: Richard W. Hoffman, JR., Clinton, NJ (US); Pravin Patel, Albuquerque, NM (US); Tansen Varghese, Albuquerque, NM (US)

(73) Assignee: Emcore Solar Power, Inc., Albuquerque, NM (US)

(21) Appl. No.: 13/104,451

(22) Filed: May 10, 2011

(51) Int. Cl. H01L 31/06

(52) U.S. Cl. 136/255

(57) ABSTRACT

A photovoltaic solar cell for producing energy from the sun including a germanium substrate including a first photoactive junction and forming a bottom solar subcell; a gallium arsenide middle cell disposed on said substrate; an indium gallium phosphide top cell disposed over the middle cell; and a surface grid including a plurality of spaced apart grid lines, wherein the grid lines have a thickness greater than 7 microns, and each grid line has a cross-section in the shape of a trapezoid with a cross-sectional area between 45 and 55 square microns.

### BACKGROUND OF THE INVENTION

1. Field of the Invention

The present invention relates generally to the design of solar cells for either space or concentrator terrestrial solar power systems for the conversion of sunlight into electrical energy, and, more particularly to an arrangement including a grid configuration on the solar cell.

2. Description of the Related Art

Commercially available silicon solar cells for terrestrial solar power application have efficiencies ranging from 8% to 15%. Compound semiconductor solar cells, based on III-V compounds, have 28% efficiency in normal operating conditions. Moreover, it is well known that concentrating solar energy onto a III-V compound semiconductor photovoltaic cell increases the cell's efficiency to over 37% efficiency under concentration.

Terrestrial solar power systems currently use silicon solar cells in view of their low cost and widespread availability. Although III-V compound semiconductor solar cells have been widely used in satellite applications, in which their power-to-weight efficiencies are more important than cost-per-watt considerations in selecting such devices, such III-V semiconductor solar cells have not yet been designed for optimum coverage of the solar spectrum present at the earth's surface (known as air mass 1.5 or AM1.5D).

In the design of both silicon and III-V compound semiconductor solar cells, one electrical contact is typically placed on a light absorbing or front side of the solar cell and a second contact is placed on the back side of the cell. A photoactive semiconductor is disposed on a light-absorbing side of the substrate and includes one or more p-n junctions, which creates electron flow as light is absorbed within the cell. Conductive grid lines extend over the top surface of the cell to capture this electron flow which then connect into the front contact or bonding pad.

An important aspect of specifying the design of a solar cell is the physical structure (composition, bandgaps, and layer thicknesses) of the semiconductor material layers constituting the solar cell. Solar cells are often fabricated in vertical, multijunction structures to utilize materials with different bandgaps and convert as much of the solar spectrum as possible. One type of multijunction structure useful in the design according to the present invention is the triple junction solar cell structure consisting of a germanium bottom cell, a gallium arsenide (GaAs) middle cell, and an indium gallium phosphide (InGaP) top cell.

### SUMMARY OF THE INVENTION

### 1. Objects of the Invention

It is an object of the present invention to provide an improved III-V compound semiconductor multijunction solar cell for terrestrial power applications with a grid configuration that permits the solar cell to produce in excess of 35 milliwatts of peak DC power per square centimeter of cell area per sun at AM1.5D solar irradiation.

It is an object of the present invention to provide an improved III-V compound semiconductor multijunction solar cell for space power applications with a grid configuration that permits the solar cell to produce in excess of 35 milliwatts of peak DC power per square centimeter of cell area per sun at AM0 solar irradiation.

It is still another object of the invention to provide a grid structure on the front surface of a III-V semiconductor solar cell to accommodate high current for concentrator photovoltaic terrestrial power applications.

Some implementations may achieve fewer than all of the foregoing objects.

### 2. Features of the Invention

Briefly, and in general terms, the present invention provides a concentrator photovoltaic solar cell arrangement for producing energy from the sun comprising a concentrating lens for producing a light concentration of greater than 500×; and a solar cell in the path of the concentrated light beam, the solar cell including a germanium substrate including a first photoactive junction and forming a bottom solar subcell; a gallium arsenide middle cell disposed on said substrate; an indium gallium phosphide top cell disposed over said middle cell and having a bandgap to maximize absorption in the AM1.5 spectral region; and a surface grid disposed over said top cell including a plurality of spaced apart grid lines, wherein the grid lines have a thickness greater than 7 microns, and each grid line has a cross-section in the shape of a trapezoid with a cross-sectional area between 45 and 55 square microns.

In another aspect, the present disclosure provides a photovoltaic solar cell for producing energy from the sun including a germanium substrate including a first photoactive junction and forming a bottom solar subcell; a gallium arsenide middle cell disposed on said substrate; an indium gallium phosphide top cell disposed over the middle cell; and a surface grid including a plurality of spaced apart grid lines, wherein the grid lines have a thickness greater than 7 microns, and each grid line has a cross-section in the shape of a trapezoid with a cross-sectional area between 45 and 55 square microns.

In another aspect, the present disclosure provides a photovoltaic solar cell arrangement for producing energy from the sun comprising a germanium substrate including a first photoactive junction and forming a bottom solar subcell; a gallium arsenide middle cell disposed on said substrate; an indium gallium phosphide top cell disposed over said middle cell; and a surface grid disposed over said top cell including a plurality of spaced apart grid lines, wherein the grid lines have a thickness greater than 7 microns.

In some embodiments, the surface grid lines have a the trapezoid cross-sectional shape with a width at the top of about 4.5 microns, and a width at the bottom of about 7 microns.

In some embodiments, the surface grid lines have a center-to-center pitch of about 100 microns.

In some embodiments, the surface grid lines consist of a plurality of parallel grid lines covering the top surface.

In some embodiments, the surface grid lines have an aggregate surface area that covers at least 5% of the surface area of the top cell, but less than 10% of the surface area.

In some embodiments, the surface grid lines have the aggregate surface area of grid pattern that covers about 6% of the surface area.

In some embodiments, the solar cell has an open circuit voltage (V_{oc}) of at least 3.0 volts, a responsivity at short circuit at least 0.13 amps per watt, a fill factor (FF) of at least 0.70, and produces in excess of 35 milliwatts peak DC power per square centimeter of cell area, at AM1.5D solar irradiation with conversion efficiency in excess of 35% per sun.

In some embodiments, the solar cell has an open circuit voltage (V_{oc}) of at least 3.0 volts, a responsivity at short circuit at least 0.13 amps per watt, a fill factor (FF) of at least 0.70, and produces in excess of 35 milliwatts peak DC power per square centimeter of cell area, at AM0 solar irradiation with conversion efficiency in excess of 35% per sun.

In some embodiments, the band gap of the top, middle, and bottom subcells are 1.9 eV, 1.4 eV, and 0.7 eV respectively.

In some embodiments, the top subcell has a sheet resistance of less than 300 ohms/square.

In some embodiments, the sheet resistance of the top subcell sheet resistance is about 200 ohms/square.

In some embodiments, the tunnel diode layers disposed between the subcells of the solar cell have a thickness adapted to support a current density through the tunnel diodes of between 15 and 30 amps/square centimeter.

Some implementations of the present invention may incorporate or implement fewer of the aspects and features noted in the foregoing summaries.

### BRIEF DESCRIPTION OF THE DRAWINGS

FIG. 1 is a highly enlarged cross-sectional view of a terrestrial solar cell constructed in accordance with the prior art;

FIG. 2 is a highly enlarged cross-sectional view of a terrestrial solar cell constructed in accordance with the teachings of the present disclosure;

FIG. 3 is a graph showing the efficiency of a solar cell under 500 sun illumination with an AM1.5D spectrum with a surface area of one square centimeter solar cell as a function of the thickness of the grid lines; and

FIG. 4 is a graph showing the efficiency of a solar cell under one sun illumination with an AM0 spectrum with a surface area of sixty square centimeters as a function of the thickness of the grid lines.

### DESCRIPTION OF THE PREFERRED EMBODIMENT

Details of the present invention will now be described including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of the actual embodiment nor the relative dimensions of the depicted elements, and are not drawn to scale.

The design of a typical semiconductor structure of a triple junction III-V compound semiconductor solar cell is more particularly described in U.S. Pat. No. 6,680,432, herein incorporated by reference.

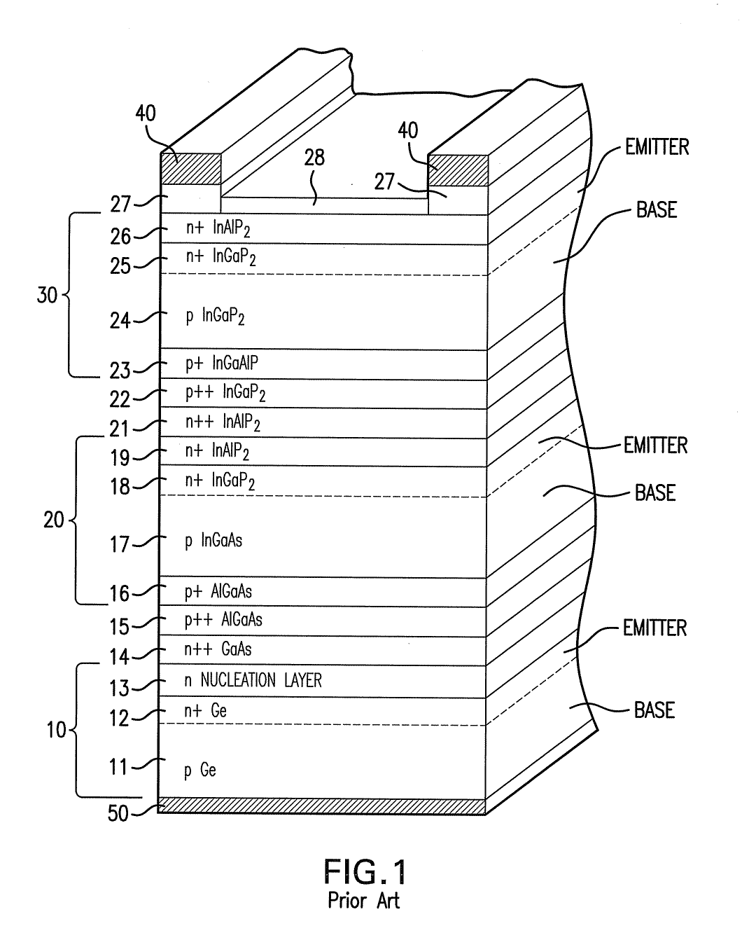

As shown in the illustrated example of FIG. 1, the bottom subcell 10 includes a substrate 11, 12 formed of p-type germanium (“Ge”), the bottom portion which also serves as a base layer of the subcell 10. A metal contact layer or pad 50 is formed on the bottom of base layer 11 to provide an electrical contact to the multijunction solar cell. The bottom subcell 10 further includes, for example, an n-type Ge emitter region 12, and an n-type nucleation layer 13. The nucleation layer 13 is deposited over the substrate 11, 12, and the emitter layer 12 is formed in the Ge substrate by diffusion of dopants from upper layers into the Ge substrate, thereby changing upper portion 12 of the p-type germanium substrate to an n-type region 12. A heavily doped n-type gallium arsenide layer 14 is deposited over the nucleation layer 13, and is a source of arsenic dopants into the emitter region 12.

Although the growth substrate and base layer 11 is preferably a p-type Ge growth substrate and base layer, other semiconductor materials may be also be used as the growth substrate and base layer, or only as a growth substrate. Examples of such substrates include, but not limited to, GaAs, InP, GaSb, InAs, InSb, GaP, Si, SiGe, SiC, Al₂O₃, Mo, stainless steel, soda-lime glass, and SiO₂

Heavily doped p-type aluminum gallium arsenide (“Al GaAs”) and (“GaAs”) tunneling junction layers 14, 15 may be deposited over the nucleation layer 13 to form a tunnel diode and provide a low resistance pathway between the bottom subcell and the middle subcell 20.

The middle subcell 20 includes a highly doped p-type aluminum gallium arsenide (“AlGaAs”) back surface field (“BSF”) layer 16, a p-type InGaAs base layer 17, a highly doped n-type indium gallium phosphide (“InGaP₂”) emitter layer 18 and a highly doped n-type indium aluminum phosphide (“AlInP₂”) window layer 19.

The window layer typically has the same doping type as the emitter, but with a higher doping concentration than the emitter. Moreover, it is often desirable for the window layer to have a higher band gap than the emitter, in order to suppress minority-carrier photogeneration and injection in the window, thereby reducing the recombination that would otherwise occur in the window layer. Note that a variety of different semiconductor materials may be used for the window, emitter, base and/or BSF layers of the photovoltaic cell, including AlInP, AlAs, AlP, AlGaInP, AlGaAsP, AlGaInAs, AlGaInPAs, GalnP, GaInAs, GalnPAs, AlGaAs, AlInAs, AlInPAs, GaAsSb, AlAsSb, GaAlAsSb, AlInSb, GaInSb, AlGaInSb, AlN, GaN, InN, GaInN, AlGaInN, GaInNAs, AlGaInNAs, ZnSSe, CdSSe, and other materials and still fall within the spirit of the present invention.

The InGaAs base layer 17 of the middle subcell 20 can include, for example, approximately 1.5% Indium. Other compositions may be used as well. The base layer 17 is formed over the BSF layer 16 after the BSF layer is deposited over the tunneling junction layers 14, 15 of the bottom subcell 10.

The BSF layer 16 is provided to reduce the recombination loss in the middle subcell 20. The BSF layer 16 drives minority carriers from a highly doped region near the back surface to minimize the effect of recombination loss. Thus, the BSF layer 16 reduces recombination loss at the backside of the solar cell and thereby reduces recombination at the base layer/BSF layer interface. The window layer 19 is deposited on the emitter layer 18 of the middle subcell 20 after the emitter layer is deposited. The window layer 19 in the middle subcell 20 also helps reduce the recombination loss and improves passivation of the cell surface of the underlying junctions.

Before depositing the layers of the top cell 30, heavily doped n-type InAlP₂ and p-type InGaP₂ tunneling junction layers 21, 22 respectively may be deposited over the middle subcell 20, forming a tunnel diode.

In the embodiment of a high concentration terrestrial solar cell, the tunnel diode layers disposed between subcells have a thickness adapted to support a current density through the tunnel diodes of between 15 and 30 amps/square centimeter.

In the illustrated example, the top subcell 30 includes a highly doped p-type indium gallium aluminum phosphide (“InGaAlP”) BSF layer 23, a p-type InGaP₂ base layer 24, a highly doped n-type InGaP₂ emitter layer 25 and a highly doped n-type InAlP₂ window layer 26. The base layer 24 of the top subcell 30 is deposited over the BSF layer 23 after the BSF layer 23 is formed over the tunneling junction layers 21, 22 of the middle subcell 20. The window layer 26 is deposited over the emitter layer 25 of the top subcell after the emitter layer 25 is formed over the base layer 24. A cap layer 27 may be deposited and patterned into separate contact regions over the window layer 26 of the top subcell 30.

The cap layer 27 serves as an electrical contact from the top subcell 30 to metal grid layer 40. The sheet resistance of the top cell is less than 300 ohms/square, and in some embodiments it is about 200 ohms/square centimeters. The doped cap layer 27 can be a semiconductor layer such as, for example, a GaAs or InGaAs layer. An anti-reflection coating 28 can also be provided on the surface of window layer 26 in between the contact regions of cap layer 27.

The grid lines 40 in prior art solar cells typically extend between two bus bars on opposite sides of the cell. In the prior art, the grid lines typically had a thickness or height of 5 microns or less, a width of about 5 microns, and a pitch (i.e., distance between centers of adjacent grid lines) of about 100 microns. The aggregate surface area of the grid pattern covered between 5.0% and 10.0% of the surface area of the top cell.

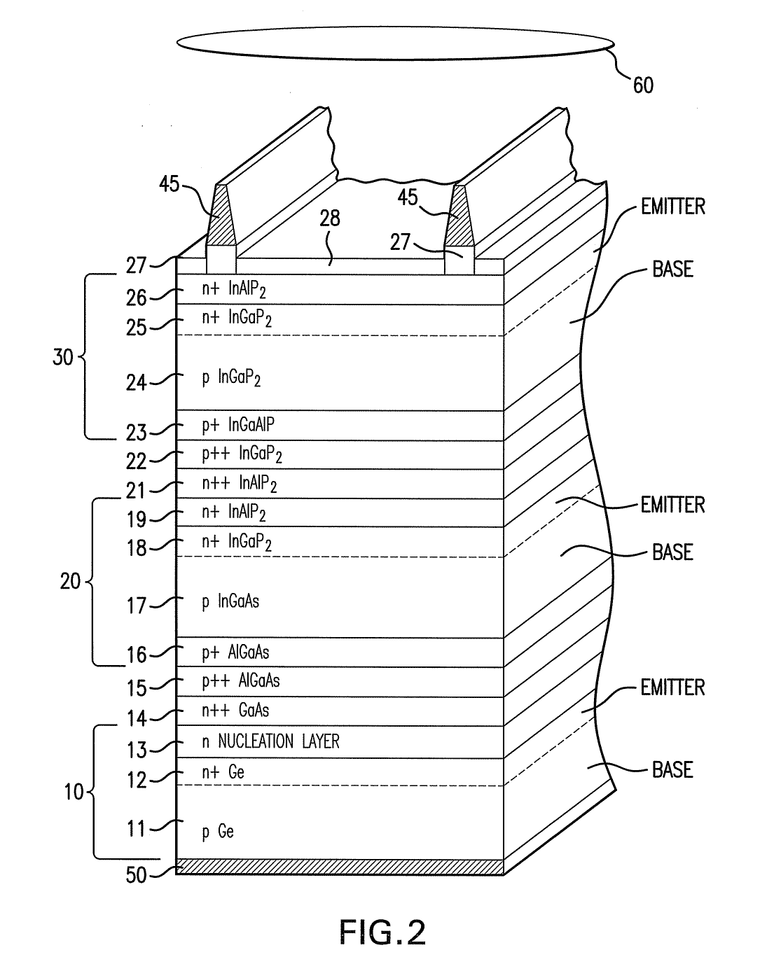

The solar cell of the present disclosure, as shown in the illustrated example of FIG. 2, has substantially the same semiconductor layers 11 through 27, metal contact layer 50, and anti-reflection coating layer 28, as that of the solar cell of FIG. 1, and such description need not be repeated here.

In some embodiments of the present disclosure, the grid lines extend between two bus bars on opposite sides of the cell. In some embodiments, each grid line may have a cross-section in the shape of a trapezoid with a cross-sectional area between 45 and 55 square microns, the size of each conductor therefore being adapted for conduction of the relatively high current created by the solar cell under high concentration.

The grid lines have a thickness or height of 7 microns or more, a width of about 5 microns, and a pitch (i.e., distance between centers of adjacent grid lines) of about 100 microns. In some embodiments, the grid lines have a the trapezoid cross-sectional shape with a width at the top of about 4.5 microns, and a width at the bottom of about 7 microns.

The aggregate surface area of the grid pattern covers between 5.0% and 10.0% of the surface area of the top cell. The grid pattern and line dimensions are selected to carry the relatively high current produced by the solar cell. In some embodiments, aggregate surface area of the grid pattern covers 6% of the surface area of the top cell.

In some embodiments, such as for terrestrial power applications, a concentrating lens 60 or other optics may be disposed above the solar cell and used to focus the incoming sunlight to a magnification of 500× or more on the surface of the cell.

In some embodiments, the resulting solar cell has band gaps of 1.9 eV, 1.4 eV and 0.7 eV for the top, middle, and bottom subcells. In some embodiments, the solar cell has an open circuit voltage (V_{oc}) of at least 3.0 volts, a responsivity at short circuit at least 0.13 amps per watt, a fill factor (FF) of at least 0.70, and an efficiency at least 35% under air mass 1.5 (AM1.5D) or similar terrestrial spectrum at 25 degrees Centigrade, when illuminated by concentrated sunlight by a factor in excess of 500×, so as to produce in excess of 35 milliwatts of peak DC power per square centimeter of cell area.

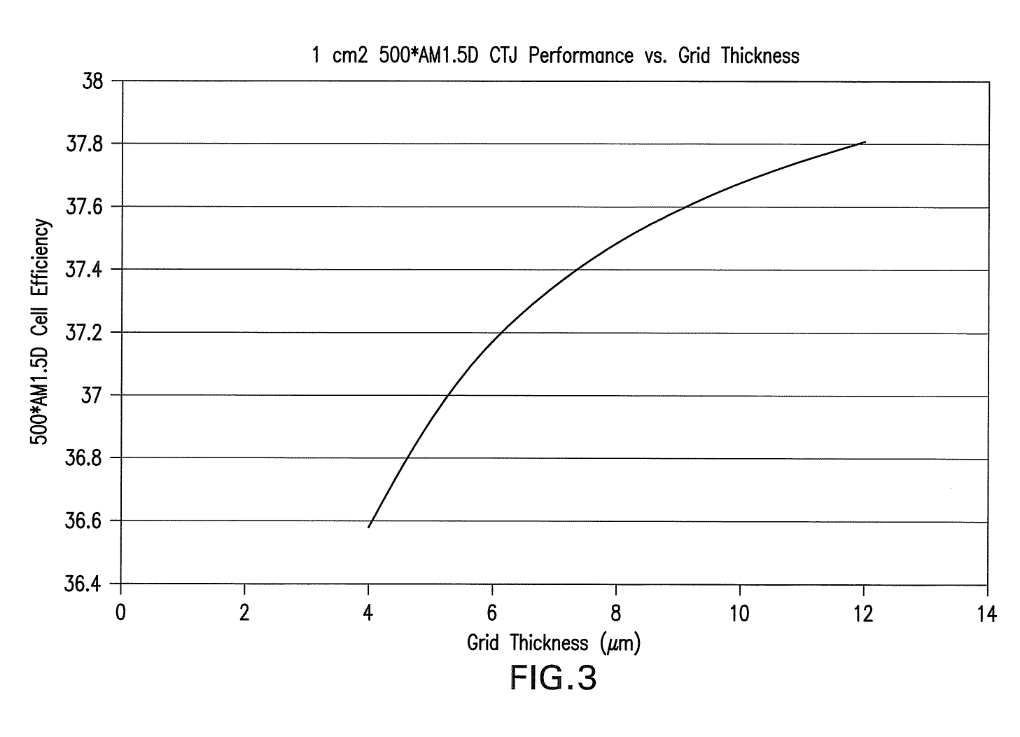

FIG. 3 is a graph showing the efficiency of a solar cell under 500 sun illumination with am AM1.5D spectrum with a surface area of one square centimeter solar cell as a function of the thickness of the grid lines. Such a solar cell (identified as a model CTJ) is suitable for terrestrial applications in concentrator photovoltaic systems which use lenses or other optics to focus the incoming sun beams on the cell at a magnification of 500 times or more. The use of thick grid lines (such as a thickness of 7 microns or more) results in a substantial improvement in cell efficiency. Limitations of lithography and processing considerations may make the achievement of grid thicknesses at the higher end of the graph (i.e. ten microns or more) less practical from a production or reliability standpoint using current production technology, but that should not detract from the teaching of the present disclosure.

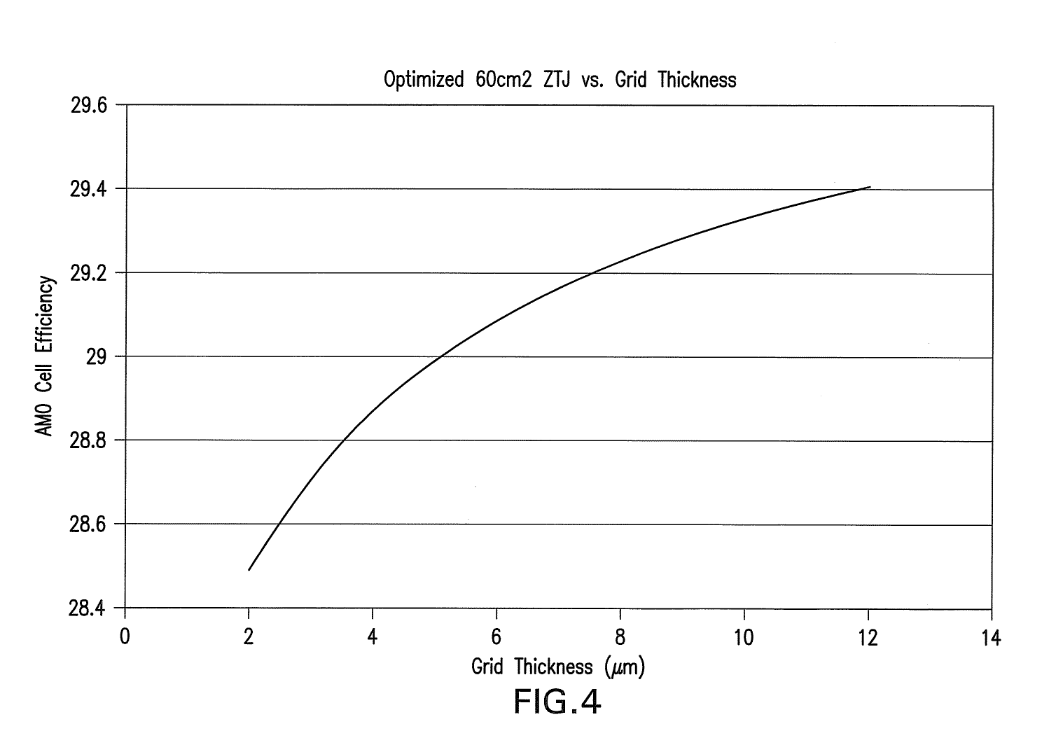

FIG. 4 is a graph showing the efficiency of a solar cell under one sun illumination with am AM0 spectrum with a surface area of sixty square centimeters as a function of the thickness of the grid lines. Such a solar cell (identified as a model ZTJ) is suitable for space applications in photovoltaic systems which operate at one sun (i.e., do not employ magnification of the incoming sun beams). The use of thick grid lines (such as a thickness of 7 microns or more) results in a substantial improvement in cell efficiency. Limitations of lithography and processing considerations may make the achievement of grid thicknesses at the higher end of the graph (i.e. ten microns or more) less practical from a production or reliability standpoint using current production technology, but that should not detract from the teaching of the present disclosure.

Although the invention has been described in certain specific embodiments of semiconductor structures, and grid designs, many additional modifications and variations would be apparent to those skilled in the art.

It will be understood that each of the elements described above, or two or more together, also may find a useful application in other types of terrestrial solar cell systems and constructions differing from the types described above.

While the aspect of the invention has been illustrated and described as embodied in a solar cell semiconductor structure using III-V compound semiconductors, it is not intended to be limited to the details shown, since various modifications and structural changes may be made without departing in any way from the spirit of the present invention.

1. A concentrator photovoltaic solar cell arrangement for producing energy from the sun comprising:
a concentrating lens for producing a light concentration of greater than 500×; and
a solar cell in the path of the concentrated light beam, including
a germanium substrate including a first photoactive junction and forming a bottom solar subcell;
a gallium arsenide middle cell disposed on said substrate;
an indium gallium phosphide top cell disposed over said middle cell and having a bandgap to maximize absorption in the AM1.5 spectral region; and
a surface grid disposed over said top cell including a plurality of spaced apart grid lines, wherein the grid lines have a thickness greater than 7 microns, and each grid line has a cross-section in the shape of a trapezoid with a cross-sectional area between 45 and 55 square microns and adapted for conduction of the relatively high current created by the solar cell.

2. An arrangement as claimed in claim 1, wherein the trapezoid shape has a width at the top of about 4.5 microns, and a width at the bottom of about 7 microns.

3. An arrangement as claimed in claim 1, wherein the grid lines have a center-to-center pitch of about 100 microns.

4. An arrangement as claimed in claim 1, wherein the grid pattern consists of a plurality of parallel grid lines covering the top surface.

5. An arrangement as claimed in claim 1, wherein the aggregate surface area of grid pattern covers at least 5% of the surface area of the top cell, but less than 10% of the surface area.

6. An arrangement as claimed in claim 1, wherein the aggregate surface area of grid pattern covers about 6% of the surface area.

7. An arrangement as claimed in claim 1, wherein the solar cell has an open circuit voltage (V_{oc}) of at least 3.0 volts, a responsivity at short circuit at least 0.13 amps per watt, a fill factor (FF) of at least 0.70, and produces in excess of 35 milliwatts peak DC power per square centimeter of cell area, at AM1.5 solar irradiation with conversion efficiency in excess of 35% per sun.

8. An arrangement as claimed in claim 1, wherein the band gap of the top, middle, and bottom subcells are 1.9 eV, 1.4 eV, and 0.7 eV respectively.

9. An arrangement as claimed in claim 1, wherein the top subcell has a sheet resistance of less than 300 ohms/square.

10. A solar cell as claimed in claim 9, wherein the sheet resistance of the top subcell sheet resistance is about 200 ohms/square.

11. A solar cell as claimed in claim 1, further comprising tunnel diode layers disposed between the subcells of the solar cell having a thickness adapted to support a current density through the tunnel diodes of between 15 and 30 amps/square centimeter.

12. A photovoltaic solar cell arrangement for producing energy from the sun comprising:
a germanium substrate including a first photoactive junction and forming a bottom solar subcell;
a gallium arsenide middle cell disposed on said substrate;
an indium gallium phosphide top cell disposed over said middle cell; and
a surface grid disposed over said top cell including a plurality of spaced apart grid lines, wherein the grid lines have a thickness greater than 7 microns, and each grid line has a cross-section in the shape of a trapezoid with a cross-sectional area between 45 and 55 square microns.

13. An arrangement as claimed in claim 12, wherein the trapezoid shape has a width at the top of about 4.5 microns, and a width at the bottom of about 7 microns.

14. An arrangement as claimed in claim 12, wherein the grid lines have a center-to-center pitch of about 100 microns.

15. An arrangement as claimed in claim 12, wherein the grid pattern consists of a plurality of parallel grid lines covering the top surface.

16. An arrangement as claimed in claim 12, wherein the aggregate surface area of grid pattern covers at least 5% of the surface area of the top cell, but less than 10% of the surface area.

17. An arrangement as claimed in claim 12, wherein the aggregate surface area of grid pattern covers about 6% of the surface area.

18. An arrangement as claimed in claim 12, wherein the band gap of the top, middle, and bottom subcells are 1.9 eV, 1.4 eV, and 0.7 eV respectively.

19. An arrangement as claimed in claim 12, wherein the top subcell has a sheet resistance of less than 300 ohms/square.

20. A solar cell as claimed in claim 19, wherein the sheet resistance of the top subcell sheet resistance is about 200 ohms/square.
